(19) United States
(12) Patent Application Publication
(10) Pub. No.: US 2007/0280403 A1
(43) Pub. Date: Dec. 6, 2007

(54) Counter outputting count signal having random count value

(75) Inventor: Byung Ryul Kim, Seoul (KR)

Correspondence Address: LOWE HAUPTMAN HAM & BERNER, LLP, 1700 DIAGONAL ROAD, SUITE 300, ALEXANDRIA, VA, 22314, US

(73) Assignee: Hynix Semiconductor Inc.

(21) Appl. No.: 11/488,839

(22) Filed: Jul. 19, 2006

(30) Foreign Application Priority Data
May 12, 2006 (KR) 2006-42973

(51) Int. Cl. H03K 25/00

(52) U.S. Cl. 377/94

(57) ABSTRACT

A counter that outputs a counting signal having a random counting value. The counter includes a clock generator and a counting circuit. The clock generator generates first and second clock signals with different phases based on an input clock signal. The counting circuit executes a counting operation and outputs a counting signal having a random counting value, in response to the first and second clock signals. The counter can output a counting signal having a random counting value. Accordingly, semiconductor devices to which the counter is applied can execute a variety of operations.

### BACKGROUND

1. Field of the Invention

The present invention relates generally to semiconductor devices, and more particularly, to a counter.

2. Discussion of Related Art

In general, a counter is generally used as a device for measuring a specific operating time (for example, the refresh cycle of DRAM) within the semiconductor memory device or a device for generating a signal having a bit value gradually increasing from an initial value (for example, an address generator of the semiconductor memory device).

In the prior art counter, when a counting operation is performed, an accumulated counting value is gradually increased or decreased. For example, a timing diagram of a counting signal COUNT, which is output by a 4-bit counter while executing the counting operation, is shown in FIG. 1. Referring to FIG. 1, when the prior art counter executes the counting operation, logic values of bits B0 to B3 of the counting signal COUNT are changed as in the following Table.

TABLE 1

Bit Value

| Counting Value | B3 | B2 | B1 | B0 |
|---|---|---|---|---|
| 0 | 0 | 0 | 0 | 0 |
| 1 | 0 | 0 | 0 | 1 |
| 2 | 0 | 0 | 1 | 0 |
| 3 | 0 | 0 | 1 | 1 |
| 4 | 0 | 1 | 0 | 0 |
| 5 | 0 | 1 | 0 | 1 |
| 6 | 0 | 1 | 1 | 0 |
| 7 | 0 | 1 | 1 | 1 |
| 8 | 1 | 0 | 0 | 0 |
| 9 | 1 | 0 | 0 | 1 |
| 10 | 1 | 0 | 1 | 0 |
| 11 | 1 | 0 | 1 | 1 |
| 12 | 1 | 1 | 0 | 0 |
| 13 | 1 | 1 | 0 | 1 |
| 14 | 1 | 1 | 1 | 0 |
| 15 | 1 | 1 | 1 | 1 |

Meanwhile, as manufacture technologies of semiconductor devices are developed, semiconductor devices having a variety of operating performances have been developed. Accordingly, there is a need for diversifying the counting operation of the counter according to the operating performances of the semiconductor devices.

### SUMMARY OF THE INVENTION

An embodiment of the present invention is that it provides a counter that can execute a variety of operations of semiconductor devices by outputting a counting signal having a random counting value.

A counter according to an aspect of the present invention includes a clock generator and a counting circuit. The clock generator generates first and second clock signals with different phases based on an input clock signal. The counting circuit executes a counting operation and outputs a counting signal having a random counting value, in response to the first and second clock signals.

A counter according to another aspect of the present invention includes a first inverter and a counting circuit. The first inverter inverts an input signal and outputs an inverted input signal. The counting circuit executes a counting operation in response to the input signal and the inverted input signal and outputs a counting signal having a random counting value. The counting signal includes first and second bits. The counting circuit includes a first flip-flop that receives an output signal in response to the input signal and outputs the first bit, and a second flip-flop that receives the first bit in response to the inverted input signal and outputs the second bit and the output signal having a logic value opposite to that of the second bit.

A counter according to further another aspect of the present invention includes a clock generator and a counting circuit. The clock generator generates first and second clock signals with different phases based on an input clock signal. The counting circuit executes a counting operation and outputs a counting signal having a random counting value in response to the first and second clock signals. The counting signal includes first to fourth bits. The counting circuit includes a first inverter that inverts the first clock signal and outputs an inverted first clock signal, a second inverter that inverts the second clock signal and outputs an inverted second clock signal, a first flip-flop that receives a first output signal and outputs the first bit in response to the first clock signal, a second flip-flop that receives the first bit, and outputs the third bit and the first output signal having a logic value opposite to that of the third bit, in response to the inverted first clock signal, a third flip-flop that receives a second output signal and outputs the second bit in response to the second clock signal, and a fourth flip-flop that receives the second bit, and outputs the fourth bit and the second output signal having a logic value opposite to that of the fourth bit, in response to the inverted second clock signal.

### BRIEF DESCRIPTION OF THE DRAWINGS

A more compete appreciation of the invention, and many of the attendant advantages thereof, will be readily apparent as the same becomes better understood by reference to the following detailed description when considered in conjunction with the accompanying drawings in which like reference symbols indicate the same or similar components, wherein:

FIG. 1 is a timing diagram illustrating bits of a counting signal generated by a counter in the related art;

FIG. 2 is a circuit diagram of a counter according to an embodiment of the present invention;

FIG. 3 is a timing diagram of signals related to the operation of a clock generator shown in FIG. 2;

FIGS. 4 and 5 are detailed circuit diagrams of a flip-flop shown in FIG. 2;

FIG. 6 is a timing diagram of signals related to the operation of the counter shown in FIG. 2;

FIG. 7 is a circuit diagram of a counter according to another embodiment of the present invention; and

FIG. 8 is a circuit diagram of a counter according to further another embodiment of the present invention.

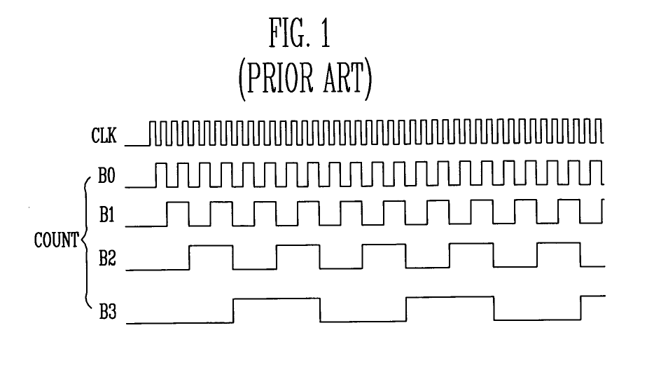

### DETAILED DESCRIPTION OF EMBODIMENTS

The present invention will now be described in detail in connection with certain exemplary embodiments with reference to the accompanying drawings.

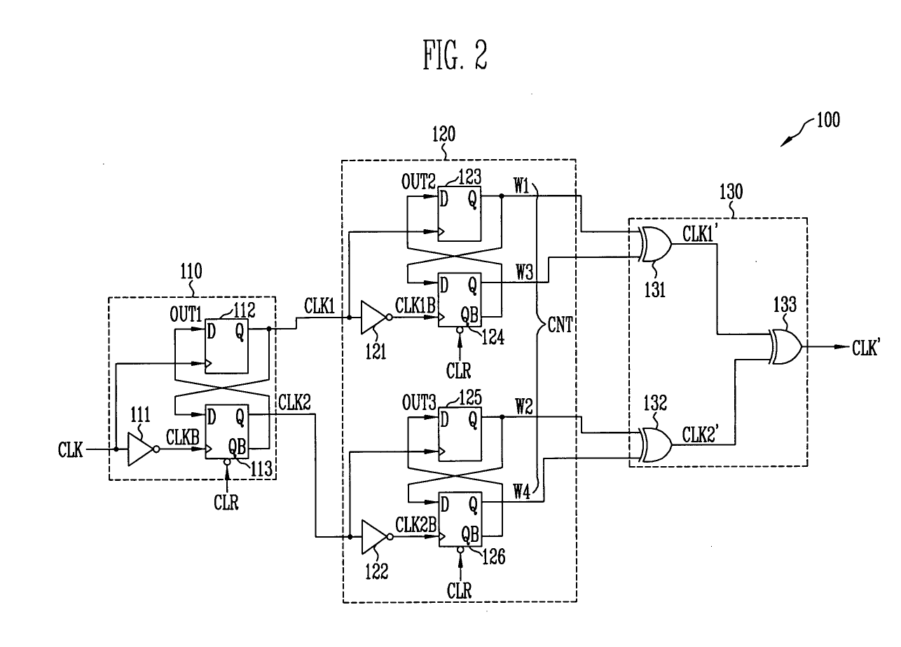

FIG. 2 is a circuit diagram of a counter according to an embodiment of the present invention.

Referring to FIG. 2, a counter 100 includes a clock generator 110 and a counting circuit 120.

The clock generator 110 generates clock signals CLK1 and CLK2 with different phases based on an input clock signal CLK. In more detail, the clock generator 110 includes an inverter 111 and D flip-flops 112 and 113. The inverter 111 inverts the input clock signal CLK and outputs an inverted input clock signal CLKB. The D flip-flop 112 receives the input clock signal CLK through a clock input terminal CK, receives an output signal OUT1 through an input terminal D, and outputs the clock signal CLK1 through the output terminal Q. The D flip-flop 113 receives the inverted input clock signal CLKB through the clock input terminal CK, receives the clock signal CLK1 through the input terminal D, and outputs the clock signal CLK2 through the output terminal Q, as well as outputting the output signal OUT1 having a logic value opposite to that of clock signal CLK2. The D flip-flop 113 is reset in response to a clear signal CLR.

The counting circuit 120 executes a counting operation in response to the clock signals CLK1, CLK2 and outputs a counting signal CNT having a random counting value. In the present embodiment, an example in which the counting signal CNT is 4 bits (i.e., the counting signal CNT includes bits W1 to W4) will be described. The counting circuit 120 includes inverters 121 and 122 and flip-flops 123 to 126. The inverter 121 inverts the clock signal CLK1 and outputs an inverted clock signal CLK1B. The inverter 122 inverts the clock signal CLK2 and outputs an inverted clock signal CLK2B. The flip-flop 123 receives an output signal OUT2 in response to the clock signal CLK and outputs a bit W1. The flip-flop 124 receives the bit W1 in response to the inverted clock signal CLK1B, and outputs a bit W3 and the output signal OUT2 having a logic value opposite to that of the bit W3. The flip-flop 125 receives an output signal OUT3 in response to the clock signal CLK2, and outputs the bit W2. The flip-flop 126 receives the bit W2 in response to the inverted clock signal CLK2B, and outputs the bit W4, and the output signal OUT3 having a logic value opposite to that of the bit W4.

The counter 100 may further include a clock restoration circuit 130. The clock restoration circuit 130 includes XOR gates 131 to 133. The XOR gate 131 outputs a restored clock signal CLK1′ in response to the bits W1 and W3. Preferably, the restored clock signal CLK1′ may have the same phase as that of the clock signal CLK1. The XOR gate 132 outputs a restored clock signal CLK2′ in response to the bits W2, W4. Preferably, the restored clock signal CLK2′ may have the same phase as that of the clock signal CLK2. The XOR gate 133 outputs a restored input clock signal CLK′ in response to the restored clock signals CLK1′, CLK2′.

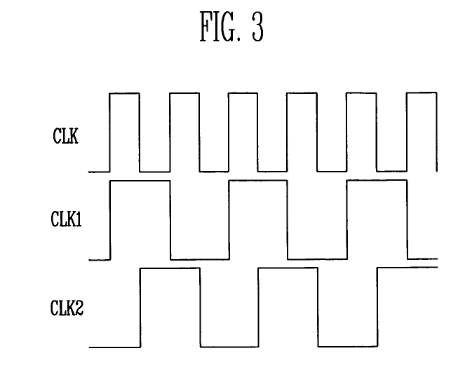

FIG. 3 is a timing diagram of signals related to the operation of the clock generator shown in FIG. 2.

Referring to FIG. 3, the clock signal CLK1 is synchronized to a rising edge of the clock signal CLK and the clock signal CLK2 is synchronized to a falling edge of the clock signal CLK, so that logic values of the clock signal CLK1 and the clock signal CLK2 are changed. From FIG. 3, it can be seen that the logic values of the clock signals CLK1, CLK2 are changed like ‘10’ →‘11’→‘01’→‘00’.

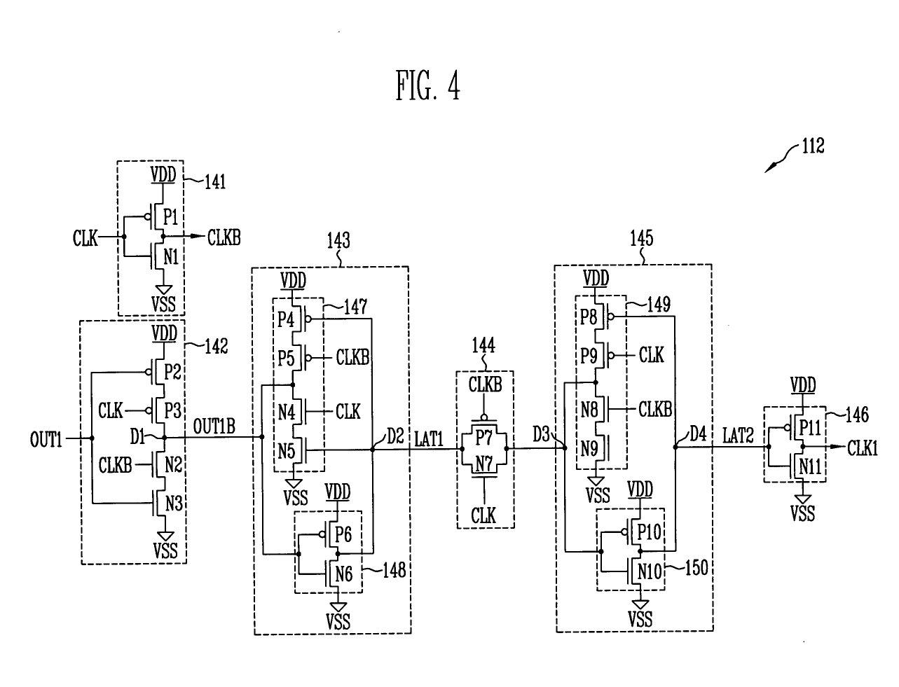

FIG. 4 is a detailed circuit diagram of the flip-flop shown 112 in FIG. 2. The flip-flops 123 and 125 of FIG. 2 have the same construction and operation as those of the flip-flop 112. Accordingly, the flip-flop 112 will be described as an example below in order to avoid redundancy.

The flip-flop 112 includes inverters 141, 142 and 146, latch circuits 143 and 145, and a switch circuit 144. The inverter 141 inverts the input clock signal CLK and outputs the inverted input clock signal CLKB to the inverter 142, the latch circuits 143 and 145, and the switch circuit 144. The inverter 141 may be implemented using a CMOS inverter including a PMOS transistor P1 and a NMOS transistor N1. The construction and operation of the inverter 141 are well known to those having ordinary skill in the art and therefore will not be described.

The inverter 142 inverts the output signal OUT1 received from the flip-flop 113 and outputs the inverted output signal OUT1B, in response to the input clock signal CLK and the inverted input clock signal CLKB. Preferably, when the clock signal CLK is logical low, the inverter 142 inverts the output signal OUT1 and outputs the inverted output signal OUT1B. The inverter 142 includes PMOS transistors P2, P3 and NMOS transistors N2 and N3. The PMOS transistor P2 has a source to which an internal voltage VDD is inputted and a gate to which the output signal OUT1 is inputted. The PMOS transistor P2 is turned on or off in response to the output signal OUT1. The PMOS transistor P3 has a source connected to a drain of the PMOS transistor P2, a gate to which the input clock signal CLK is inputted, and a drain connected to a node D1. The PMOS transistor P3 is turned on or off in response to the clock signal CLK. The NMOS transistor N2 has a drain connected to the node D1 and a gate to which the inverted clock signal CLKB is inputted. The NMOS transistor N2 is turned on or off in response to the inverted clock signal CLKB. The NMOS transistor N3 has a drain connected to a source of the NMOS transistor N2, a gate to which the output signal OUT1 is inputted, and a source to which a ground voltage VSS is inputted. The NMOS transistor N3 is turned on or off in response to the output signal OUT1.

The latch circuit 143 latches the inverted output signal OUT1B and outputs a latch signal LAT1, in response to the input clock signal CLK and the inverted input clock signal CLKB. The latch circuit 143 includes inverters 147 and 148 connected to the nodes D1 and D2. In more detail, the node D1 is connected to an output terminal of the inverter 147 and an input terminal of the inverter 148, and the node D2 is connected to an input terminal of the inverter 147 and an output terminal of the inverter 148. The inverter 147 includes PMOS transistors P4, P5 and NMOS transistors N4 and N5. The PMOS transistors P4 and P5 and the NMOS transistors N4 and N5 have the same construction and operation as those of the PMOS transistors P2 and P3 and the NMOS transistors N2 and N3 and therefore will not be described. The inverter 147 operates in response to the input clock signal CLK and the inverted input clock signal CLKB. The inverter 148 inverts the inverted output signal OUT1B and outputs an inverted signal to the node D2 as the latch signal LAT1.

The switch circuit 144 is connected between the latch circuits 143 and 145 and transfers the latch signal LAT1 to the latch circuit 145 in response to the input clock signal CLK and the inverted input clock signal CLKB. The switch circuit 144 includes a PMOS transistor P7 and a NMOS transistor N7. The PMOS transistor P7 is connected between the nodes D2 and D3 and is turned on or off in response to the inverted input clock signal CLKB. The NMOS transistor N7 is connected between the nodes D2 and D3 and is turned on or off in response to the input clock signal CLK. Preferably, when the input clock signal CLK is a logical high, the switch circuit 144 outputs the latch signal LAT1 to the latch circuit 145.

The latch circuit 145 latches the latch signal LAT1 received from the switch circuit 144 and outputs a latch signal LAT2, in response to the input clock signal CLK and the inverted input clock signal CLKB. The latch circuit 145 includes inverters 149 and 150 connected to the nodes D3 and D4. In more detail, the node D3 is connected to an output terminal of the inverter 149 and an input terminal of the inverter 150, and the node D4 is connected to an input terminal of the inverter 149 and an output terminal of the inverter 150.

The inverter 149 includes PMOS transistors P8 and P9 and NMOS transistors N8 and N9. The PMOS transistors P8 and P9 and the NMOS transistors N8 and N9 have the same construction and operation as those of the PMOS transistors P2 and P3 and the NMOS transistors N2 and N3 and therefore will not be described. The inverter 149 operates in response to the input clock signal CLK and the inverted input clock signal CLKB. The inverter 150 inverts the latch signal LAT1 and outputs an inverted signal to a node D4 as the latch signal LAT2. The inverter 146 inverts the latch signal LAT2 and outputs an inverted signal as the clock signal CLK1. The inverter 146 includes a PMOS transistor P11 and a NMOS transistor N1.

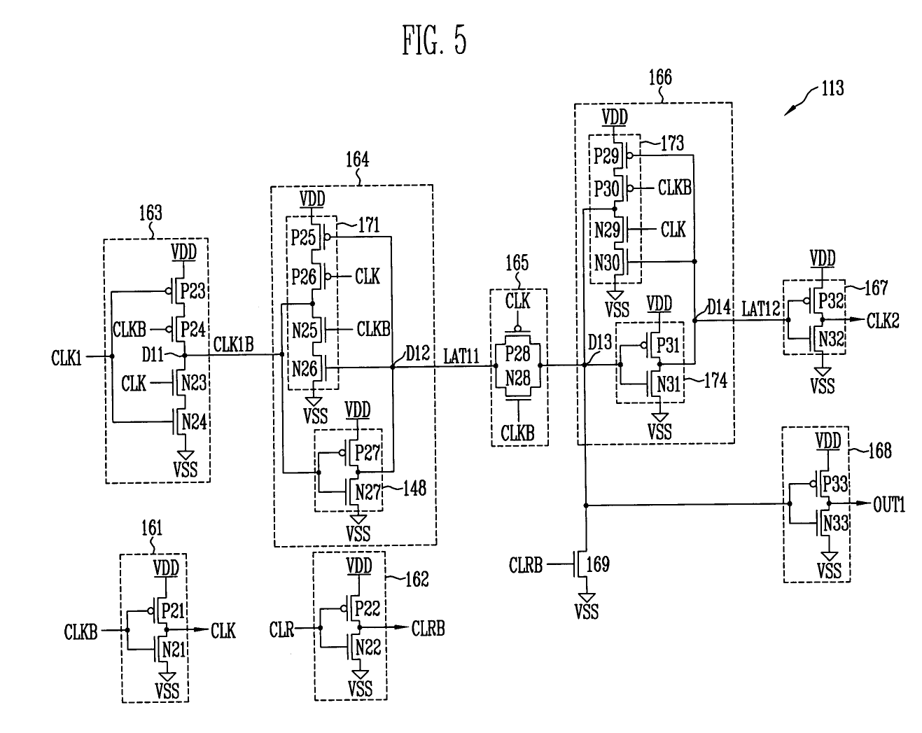

FIG. 5 is a detailed circuit diagram of the flip-flop shown 113 in FIG. 2. The flip-flops 124 and 126 of FIG. 2 have the same construction and operation as those of the flip-flop 113. Accordingly, to simplify description, only the construction and operation of the flip-flop 113 will be described as an example.

The flip-flop 113 includes inverters 161, 162, 163, 167 and 168, latch circuits 164 and 166, a switch circuit 165, and a reset circuit 169.

The inverter 161 inverts the inverted input clock signal CLKB and outputs the input clock signal CLK to the inverter 163, the latch circuits 164 and 166, and the switch circuit 165, respectively. The inverter 161 includes a PMOS transistor P21 and a NMOS transistor N21.

The inverter 162 inverts a clear signal CLR and outputs an inverted clear signal CLRB. The inverter 162 includes a PMOS transistor P22 and a NMOS transistor N22.

The inverter 163 inverts the clock signal CLK1 and outputs the inverted clock signal CLK1B, in response to the inverted input clock signal CLKB and the input clock signal CLK. The inverter 163 includes PMOS transistors P23 and P24 and NMOS transistors N23 and N24. The PMOS transistors P23 and P24 and the NMOS transistors N23 and N24 have the same construction and operation as those of the PMOS transistors P2 and P3 and the NMOS transistors N2 and N3 and therefore will not be described.

The latch circuit 164 latches the inverted clock signal CLK1B and outputs a latch signal LAT11, in response to the input clock signal CLK and the inverted input clock signal CLKB. The latch circuit 164 includes inverters 171 and 172 connected to the nodes D11 and D12. In more detail, the node D11 is connected to an output terminal of the inverter 171 and an input terminal of the inverter 172, and the node D12 is connected to an input terminal of the inverter 171 and an output terminal of the inverter 172. The inverter 171 includes PMOS transistors P25 and P26 and NMOS transistors N25 and N26. The PMOS transistors P25 and P26 and the NMOS transistors N25 and N26 have the same construction and operation as those of the PMOS transistors P2 and P3 and the NMOS transistors N2 and N3. The inverter 171 operates in response to the input clock signal CLK and the inverted input clock signal CLKB. The inverter 172 inverts the inverted clock signal CLK1B and outputs an inverted signal to the node D12 as the latch signal LAT11.

The switch circuit 165 is connected between the latch circuits 164 and 166 and outputs the latch signal LAT11 to an input node D13 of the latch circuit 166, in response to the input clock signal CLK and the inverted input clock signal CLKB. The switch circuit 165 includes a PMOS transistor P28 and a NMOS transistor N28. The PMOS transistor P28 is connected between the nodes D12 and D13 and is turned on or off in response to the input clock signal CLK. The NMOS transistor N28 is connected between the nodes D12, D13 and is turned on or off in response to the inverted input clock signal CLKB. Preferably, when the input clock signal CLK is a logical low, the switch circuit 165 outputs the latch signal LAT11 to the input node D13.

The latch circuit 166 latches the latch signal LAT11, which is received from the switch circuit 165 through the input node D13, and outputs a latch signal LAT12, in response to the input clock signal CLK and the inverted input clock signal CLKB. The latch circuit 166 includes inverters 173 and 174 connected to nodes D13 and D14. In more detail, the node D13 is connected to an output terminal of the inverter 173 and an input terminal of the inverter 174, and the node D14 is connected to an input terminal of the inverter 173 and an output terminal of the inverter 174. The inverter 173 includes PMOS transistors P29 and P30 and NMOS transistors N29 and N30. The PMOS transistors P29 and P30 and the transistors N29 and N30 have the same construction and operation as those of the PMOS transistors P2 and P3 and the NMOS transistors N2 and N3 and therefore will not be described for simplicity. The inverter 173 operates in response to the input clock signal CLK and the inverted input clock signal CLKB. The inverter 174 inverts the latch signal LAT11 and outputs an inverted signal to the node D14 as the latch signal LAT12.

The inverter 167 inverts the latch signal LAT12 and outputs an inverted signal as the clock signal CLK2. The inverter 167 includes a PMOS transistor P11 and a NMOS transistor N1.

The inverter 168 inverts the latch signal LAT11, which are received from the switch circuit 165 through the node D13, and outputs an inverted signal as the output signal OUT1. The inverter 168 includes a PMOS transistor P33 and a NMOS transistor N33.

The reset circuit 169 discharges the node D13 to the ground voltage VSS in response to the inverted clear signal CLRB, thereby resetting the latch circuit 166. The reset circuit 169 may be implemented using a NMOS transistor. In this case, the reset circuit 169 discharges the node D13 to the ground voltage VSS when the inverted clear signal CLRB is a logical high.

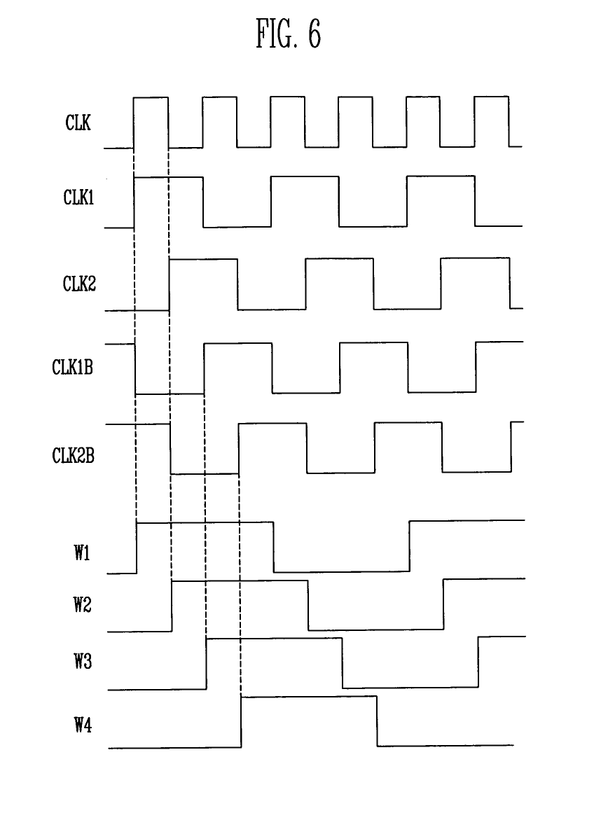

The operation of the counter 100 will be described below with reference to FIG. 6.

If the clear signal CLR becomes initially a logical low during a set time, the D flip-flop 113 of the clock generator 110 and the flip-flops 124 and 126 of the counting circuit 120 are reset in response to the clear signal CLR. As a result, the D flip-flops 113, 124 and 126 output the output signals OUT1, OUT2 and OUT3, respectively, as a logical high. Thereafter, if the clock signal CLK1 is toggled, the D flip-flop 112 of the clock generator 110 toggles the clock signal CLK1 every rising edge of the clock signal CLK. Furthermore, the D flip-flop 113 toggles the clock signal CLK2 and the output signal OUT1, respectively, every falling edge of the clock signal CLK.

In more detail, at a first rising edge of the clock signal CLK, the D flip-flop 112 receives the output signal OUT1 and outputs the clock signal CLK1 as a logical high. Furthermore, at a first falling edge of the clock signal CLK, the D flip-flop 113 receives the clock signal CLK1 and outputs the clock signal CLK2 as a logical high and the output signal OUT1 as a logical low. Thereafter, at a second rising edge of the clock signal CLK, the D flip-flop 112 receives the output signal OUT1 and outputs the clock signal CLK1 as a logical low. Furthermore, at a second falling edge of the clock signal CLK, the D flip-flop 113 receives the clock signal CLK1 and outputs the clock signal CLK2 as a logical low and the output signal OUT1 as a logical high.

Thereafter, whenever the clock signal CLK is toggled, the D flip-flops 112 and 113 repeat the above-mentioned operation process. Consequently, while the clock signal CLK is toggled, logic values of the clock signals CLK1, CLK2 are consecutively changed like ‘10’→‘11’→‘01’→‘00’→‘10’ . . . .

The inverters 121 and 122 of the counting circuit 120 inverts the clock signals CLK1 and CLK2, respectively, and output the inverted clock signals CLK1B and CLK2B, respectively. The D flip-flops 123 to 126 of the counting circuit 120 operate in a similar way as the D flip-flops 112 and 113. The D flip-flop 123 toggles the bit W1 of the counting signal CNT every riding edge of the clock signal CLK1 and the D flip-flop 124 toggles the bit W2 of the counting signal CNT every rising edge of the inverted clock signal CLK1B.

Furthermore, the D flip-flop 125 toggles the bit W3 of the counting signal CNT every riding edge of the clock signal CLK2 and the D flip-flop 126 toggles the bit W4 of the counting signal CNT every riding edge of the inverted clock signal CLK2B. Consequently, logic values of the bits W1 to W4 of the counting signal CNT and counting values are randomly changed as illustrated in the following table.

TABLE 2

| Counting Value | | | | | |
|---|---|---|---|---|---|
| When least | When least | | | | |
| significant bit is | significant bit is | Bit Value | | | |
| “W1” | “W4” | W1 | W2 | W3 | W4 |
| 1 | 8 | 1 | 0 | 0 | 0 |
| 3 | 12 | 1 | 1 | 0 | 0 |
| 7 | 14 | 1 | 1 | 1 | 0 |
| 15 | 15 | 1 | 1 | 1 | 1 |
| 14 | 7 | 0 | 1 | 1 | 1 |
| 12 | 3 | 0 | 0 | 1 | 1 |
| 8 | 1 | 0 | 0 | 0 | 1 |
| 0 | 0 | 0 | 0 | 0 | 0 |

Meanwhile, the input clock signal CLK inputted to the counter 100 may be restored by the clock restoration circuit 130. The XOR gate 131 of the clock restoration circuit 130 outputs a restored clock signal CLK1′ in response to the bits W1 and W3. The XOR gate 132 of the clock restoration circuit 130 outputs a restored clock signal CLK2′ in response to the bits W2 and W4. The XOR gate 133 of the clock restoration circuit 130 outputs the restored input clock signal CLK′ in response to the restored clock signals CLK1′ and CLK2′. The relationship between the input clock signal CLK and the clock signals CLK1 and CLK2 can be repressed in the following logic operation equation.

CLK=CLK1 XOR CLK2,

CLK1=CLK XOR CLK2,

CLK2=CLK XOR CLK1 [Equation 1]

Furthermore, the relationship between the input clock signal CLK and the bits W1 to W4 can be repressed in the following logic operation equation.

CLK=W1 XOR W2 XOR W3 XOR W4,

W1=CLK XOR W2 XOR W3 XOR W4,

W2=CLK XOR W1 XOR W3 XOR W4,

W3=CLK XOR W1 XOR W2 XOR W4,

W4=CLK XOR W1 XOR W2 XOR W3 [Equation 2]

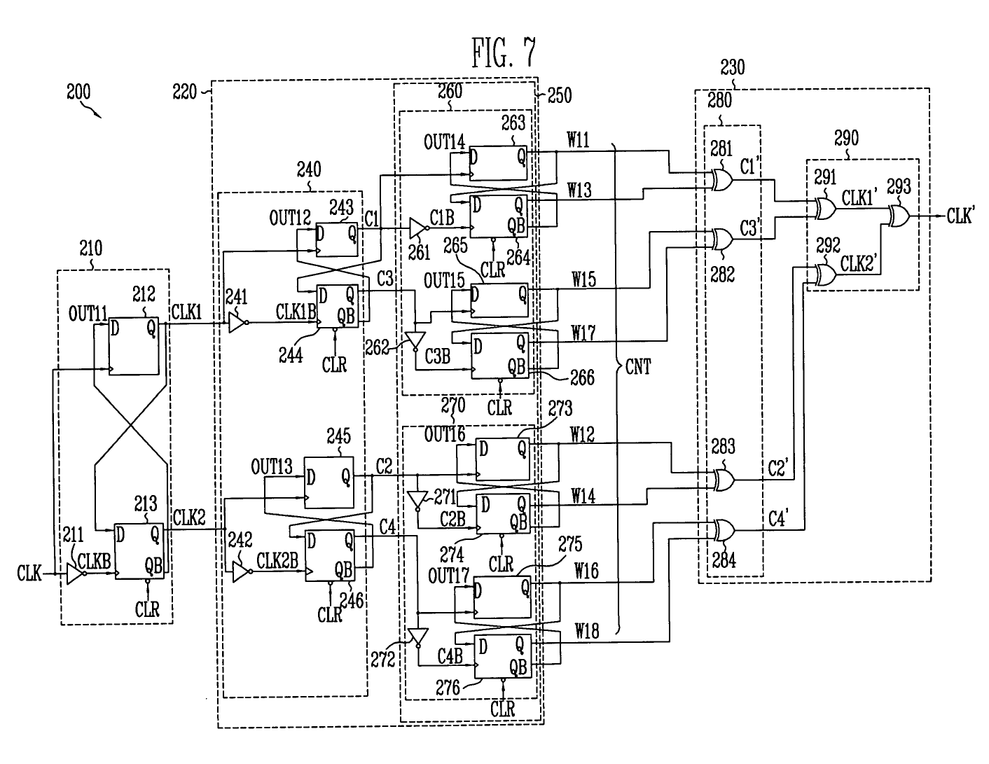

FIG. 7 is a circuit diagram of a counter according to another embodiment of the present invention.

Referring to FIG. 7, a counter 200 includes a clock generator 210, a counting circuit 220, and a clock restoration circuit 230.

The clock generator 210 outputs clock signals CLK1 and CLK2 based on an input clock signal CLK. The clock generator 210 includes an inverter 211 and D flip-flops 212 and 213. The inverter 211 and the D flip-flops 212 and 213 have the same construction and operation as those of the inverter 111 and the D flip-flops 112 and 113 and will not be described.

The counting circuit 220 executes a counting operation and outputs a counting signal CNT having a random counting value, in response to the clock signals CLK1 and CLK2. In the present embodiment, an example in which the counting signal CNT is 8 bits (i.e., the counting signal CNT includes bits W11 to W18) will be described as an example. The counting circuit 220 includes counting units 240 and 250.

The counting unit 240 executes a counting operation and outputs internal signals C1 to C4 in response to the clock signals CLK1 and CLK2 received from the clock generator 210. The counting unit 240 includes inverters 241_and 242 and D flip-flops 243 to 246. The inverters 241_and 242 and the D flip-flops 243 to 246 have the same construction and operation as those of the inverters 121_and 122 and the D flip-flops 123 to 126 and will not be described.

The counting unit 250 includes output units 260_and 270. The output unit 260 outputs bits W11, W13, W15 and W17 in response to the internal signals C1_and C3. The output unit 260 includes inverters 261_and 262 and D flip-flops 263 to 266. The inverters 261_and 262 invert the internal signals C1_and C3, respectively, and output inverted internal signals C1B_and C3B, respectively. The D flip-flop 263 outputs the bit W11 in response to the internal signal C1. Every riding edge of the internal signal C1, the D flip-flop 263 toggles the bit W11. The D flip-flop 264 outputs the bit W13 in response to the inverted internal signal C1B. Every riding edge of the inverted internal signal C1B, the D flip-flop 264 toggles the bit W13. The D flip-flop 265 outputs the bit W15 in response to the internal signal C3. Every riding edge of the internal signal C3, the D flip-flop 265 toggles the bit W15. The D flip-flop 266 outputs the bit W17 in response to an inverted internal signal C3B. Every riding edge of the inverted internal signal C3B, the D flip-flop 266 toggles the bit W17. The D flip-flops 263 to 266 have the same construction and operation as those of the D flip-flops 123 to 126 and will not be described accordingly.

The output unit 270 outputs the bits W12, W14, W16 and W18 in response to the internal signals C2_and C4. The output unit 270 includes inverters 271_and 272 and D flip-flops 273 to 276. The inverters 271_and 272 invert the internal signals C2_and C4, respectively, and output inverted internal signals C2B_and C4B, respectively. The D flip-flop 273 outputs the bit W12 in response to the internal signal C2. Every rising edge of the internal signal C2, the D flip-flop 273 toggles the bit W12. The D flip-flop 274 outputs the bit W14 in response to the inverted internal signal C2B. Every riding edge of the inverted internal signal C2B, the D flip-flop 274 toggles the bit W14. The D flip-flop 275 outputs the bit W16 in response to the internal signal C4. Every riding edge of the internal signal C4, the D flip-flop 275 toggles the bit W16. The D flip-flop 276 outputs the bit W18 in response to the inverted internal signal C4B. Every riding edge of the inverted internal signal C4B, the D flip-flop 276 toggles the bit W18. The D flip-flops 273 to 276 have the same construction and operation as those of the D flip-flops 123 to 126 and will not be described accordingly.

Consequently, logic values of the bits W11 to W18 of the counting signal CNT and counting values are randomly changed as illustrated in the following table.

TABLE 3

| Counting | | | | | | | | | |
|---|---|---|---|---|---|---|---|---|---|
| Value | | Bit Value | | | | | | | |
| A | B | W11 | W12 | W13 | W14 | W15 | W16 | W17 | W18 |
| 128 | 1 | 1 | 0 | 0 | 0 | 0 | 0 | 0 | 0 |
| 192 | 3 | 1 | 1 | 0 | 0 | 0 | 0 | 0 | 0 |
| 224 | 17 | 1 | 1 | 1 | 0 | 0 | 0 | 0 | 0 |
| 240 | 15 | 1 | 1 | 1 | 1 | 0 | 0 | 0 | 0 |
| 248 | 31 | 1 | 1 | 1 | 1 | 1 | 0 | 0 | 0 |
| 252 | 63 | 1 | 1 | 1 | 1 | 1 | 1 | 0 | 0 |
| 254 | 127 | 1 | 1 | 1 | 1 | 1 | 1 | 1 | 0 |
| 255 | 255 | 1 | 1 | 1 | 1 | 1 | 1 | 1 | 1 |
| 127 | 254 | 0 | 1 | 1 | 1 | 1 | 1 | 1 | 1 |
| 63 | 252 | 0 | 0 | 1 | 1 | 1 | 1 | 1 | 1 |
| 31 | 248 | 0 | 0 | 0 | 1 | 1 | 1 | 1 | 1 |
| 15 | 240 | 0 | 0 | 0 | 0 | 1 | 1 | 1 | 1 |
| 7 | 224 | 0 | 0 | 0 | 0 | 0 | 1 | 1 | 1 |
| 3 | 192 | 0 | 0 | 0 | 0 | 0 | 0 | 1 | 1 |
| 3 | 128 | 0 | 0 | 0 | 0 | 0 | 0 | 0 | 1 |
| 0 | 0 | 0 | 0 | 0 | 0 | 0 | 0 | 0 | 0 |

In Table 3, “A” denotes a counting value when the bit W18 is the least significant bit, and “B” denotes a counting value when the bit W1 is the least significant bit.

Meanwhile, the counter 200 may further include a clock restoration circuit 230. The clock restoration circuit 230 includes restoration circuits 280, 290. The restoration circuit 280 includes XOR gates 281 to 284. The XOR gate 281 outputs a restored internal signal C1′ in response to the bits W11, W13. The XOR gate 282 outputs a restored internal signal C3′ in response to the bits W15, W17. The XOR gate 283 outputs a restored internal signal C2′ in response to the bits W12, W14. The XOR gate 284 outputs a restored internal signal C4′ in response to the bits W16_and W18. Preferably, the restored internal signals C1′ to C4′ have the same phases as those of the internal signals C1 to C4.

The restoration circuit 290 includes XOR the gates 291 to 293. The XOR gate 291 outputs a restored clock signal CLK1′ in response to the restored internal signals C1′, C3′. The XOR gate 292 outputs a restored clock signal CLK2′ in response to the restored internal signals C2′, C4′. The XOR gate 293 outputs the restored input clock signal CLK′ in response to the restored clock signals CLK1′, CLK2′.

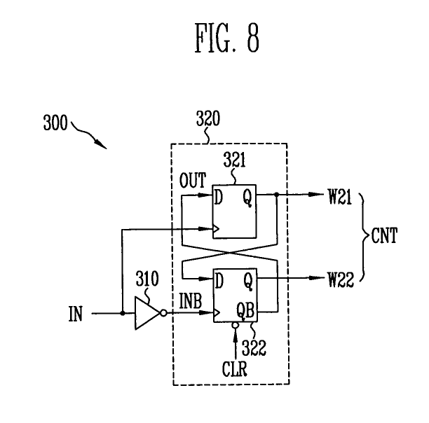

FIG. 8 is a circuit diagram of a counter according to further another embodiment of the present invention. There is shown in FIG. 8 a counter that outputs a 2-bit (i.e., bits W21, W22) counting signal CNT.

Referring to FIG. 8, a counter 300 includes an inverter 310 and a counting circuit 320. The inverter 310 inverts an input signal IN and outputs an inverted input signal INB. The counting circuit 320 executes a counting operation in response to the input signal IN and the inverted input signal INB and outputs a counting signal CNT having a random counting value. A timing diagram of the bits W21_and W22 of the counting signal CNT is similar to that of the clock signals CLK1_and CLK2 shown in FIG. 3 and a timing diagram of the input signal IN is similar to that of the input clock signal CLK shown in FIG. 3. The counting circuit 320 includes D flip-flops 321 and 322. The D flip-flops 321_and 322 have the same construction and operation as those of the D flip-flops 112_and 113 and will not be described accordingly.

In the above-mentioned embodiments, the counters 300, 100, and 200 that output the 2-bit, 8-bit, and 16-bit counting signal CNT has been described. However, the number of bits of the counting signal CNT may be changed in various ways by changing the structure of the counter. Preferably, a bit value of the counting signal CNT except for the counting signal CNT generated by the counter 300 may be set to 2N (N is a natural number greater than 1). For example, in the case where a 32-bit counting signal CNT is to be generated, two D flip-flops may be further connected to output terminals of the D flip-flops 263 to 266 and 273 to 276 of the counting circuit 220 shown in FIG. 7, respectively.

As described above, the counter according to the present invention can output a counting signal having a random counting value. Accordingly, semiconductor devices to which the counter is applied can execute a variety of operations.

While the invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. An n-bit counter, where n is an integer greater than 0, comprising:
a clock generator that generates first and second clock signals with different phases based on an input clock signal; and
a counting circuit that executes a counting operation and outputs a counting signal in response to the first and second clock signals, wherein each value from zero (0) to 2ⁿ minus one (1) is outputted every 2ⁿ cycles of the input clock in a non-consecutive, non-monotonically increasing or decreasing fashion.

2. The counter of claim 1, wherein the clock generator comprises:
a first inverter that inverts the input clock signal and outputs an inverted input clock signal;
a first flip-flop that receives an output signal of a second flip-flop and outputs the first clock signal, in response to the input clock signal; and
a second flip-flop that receives the first clock signal and outputs the second clock signal and the output signal having a logic value opposite to that of the second clock signal in response the inverted input clock signal.

3. The counter of claim 2, wherein the first flip-flop comprises a D flip-flop that receives the input clock signal through a clock input terminal, receives the output signal of the second flip-flop through a D input terminal, and outputs the first clock signal through the output terminal.

4. The counter of claim 2, wherein the first flip-flop comprises:
a second inverter that inverts the output signal of the second flip-flop and outputs an inverted output signal, in response to the input clock signal and an inverted input clock signal;
a first latch circuit that latches the inverted output signal and outputs a first latch signal, in response to the input clock signal and the inverted input clock signal;
a second latch circuit that latches the first latch signal and outputs a second latch signal, in response to the input clock signal and the inverted input clock signal;
a switch circuit connected between the first latch circuit and the second latch circuit, for transferring the first latch signal to the second latch circuit in response to the input clock signal and the inverted input clock signal;
a third inverter that inverts the input clock signal and outputs the inverted input clock signal to the second inverter, the first latch circuit, the second latch circuit and the switch circuit; and
a fourth inverter that inverts the second latch signal and outputs an inverted signal as the first clock signal.

5. The counter of claim 2, wherein the second flip-flop comprises a D flip-flop that receives the inverted input clock signal through a clock input terminal, receives the first clock signal through a D input terminal, outputs the second clock signal through the first output terminal, and outputs the output signal through the second output terminal, wherein the D flip-flop is reset in response to a clear signal received through a clear input terminal.

6. The counter of claim 2, wherein the second flip-flop comprises:
a second inverter that inverts the first clock signal and outputs an inverted first clock signal, in response to the inverted input clock signal and an input clock signal;
a first latch circuit that latches the inverted first clock signal and outputs a first latch signal, in response to the input clock signal and the inverted input clock signal;
a second latch circuit that latches the first latch signal and outputs a second latch signal, in response to the input clock signal and the inverted input clock signal;
a switch circuit connected between the first latch circuit and an input node of the second latch circuit, for transferring the first latch signal to the input node in response to the input clock signal and the inverted input clock signal;
a third inverter that inverts the inverted input clock signal and outputs the input clock signal to the second inverter, the first latch circuit, the second latch circuit, and the switch circuit;
a fourth inverter that inverts the second latch signal and outputs an inverted signal as the second clock signal; and
a fifth inverter that inverts the first latch signal received from the switch circuit through the input node and outputs an inverted signal as the output signal.

7. The counter of claim 6, wherein the second flip-flop further comprises:
a sixth inverter that inverts a clear signal and outputs an inverted clear signal; and
a reset circuit that discharges the input node to a ground voltage and resets the second latch circuit, in response to the inverted clear signal.

8. The counter of claim 1, wherein the counter is a four (4) bit counter outputting first to fourth bits, and the counting circuit comprises:
a first inverter that inverts the first clock signal and outputs an inverted first clock signal;
a second inverter that inverts the second clock signal and outputs an inverted second clock signal;
a first flip-flop that receives a first output signal and outputs the first bit, in response to the first clock signal;
a second flip-flop that receives the first bit and outputs the third bit and the first output signal having a logic value opposite to that of the third bit, in response to the inverted first clock signal;
a third flip-flop that receives a second output signal and outputs the second bit, in response to the second clock signal; and
a fourth flip-flop that receives the second bit and outputs the fourth bit and the second output signal having a logic value opposite to that of the fourth bit, in response to the inverted second clock signal.

9. The counter of claim 8, wherein the first flip-flop comprises a D flip-flop that receives the first clock signal through a clock input terminal, receives the first output signal through a D input terminal, and outputs the first bit through an output terminal.

10. The counter of claim 8, wherein the second flip-flop comprises a D flip-flop that receives the inverted first clock signal through a clock input terminal, receives the first bit through a D input terminal, outputs the third bit through a first output terminal, and outputs the first output signal through a second output terminal.

11. The counter of claim 8, wherein the third flip-flop comprises a D flip-flop that receives the second clock signal through the clock input terminal, receives the second output signal through a D input terminal, and outputs the second bit through an output terminal.

12. The counter of claim 8, wherein the fourth flip-flop comprises a D flip-flop that receives the inverted second clock signal through a clock input terminal, receives the second bit through a D input terminal, outputs the fourth bit through a first output terminal, and outputs the second output signal having a logic value opposite to that of the fourth bit through a second output terminal.

13. The counter of claim 8, wherein the second and fourth flip-flops are cleared in response to a clear signal.

14. The counter of claim 8, further comprising a clock restoration circuit that restores the input clock signal and the first and second clock signals based on the first to fourth bits.

15. The counter of claim 14, wherein the clock restoration circuit comprises:
a first XOR gate that outputs a restored first clock signal in response to the first bit and the third bit;
a second XOR gate that outputs a restored second clock signal in response to the second bit and the fourth bit; and
a third XOR gate that outputs a restored input clock signal in response to the restored first clock signal and the restored second clock signal.

16. The counter of claim 1, wherein the counter is an eight (8) bit counter outputting first to eighth bits, and the counting circuit comprises:
a first counting unit that executes a counting operation and outputs first to fourth internal signals, in response to the first and second clock signals; and
a second counting unit that executes a counting operation and outputs the first to eighth bits, in response to the first to fourth internal signals.

17. The counter of claim 16, wherein the first counting unit comprises:
a first inverter that inverts the first clock signal and outputs an inverted first clock signal;
a second inverter that inverts the second clock signal and outputs an inverted second clock signal;
a first flip-flop that receives a first output signal and outputs the first internal signal, in response to the first clock signal;
a second flip-flop that receives the first internal signal, and outputs the third internal signal and the first output signal having a logic value opposite to that of the third internal signal, in response to the inverted first clock signal;
a third flip-flop that receives a second output signal and outputs the second internal signal, in response to the second clock signal; and
a fourth flip-flop that receives the second internal signal and outputs the fourth internal signal and the second output signal having a logic value opposite to that of the fourth internal signal, in response to the inverted second clock signal.

18. The counter of claim 17, wherein the second and fourth flip-flops are respectively reset in response to a clear signal.

19. The counter of claim 16, wherein the second counting unit comprises:
a first output unit that outputs the first, third, fifth, and seventh the bits in response to the first and third internal signals; and
a second output unit that outputs the second, fourth, sixth, and eighth bits in response to the second and fourth internal signals.

20. The counter of claim 19, wherein the first output unit comprises:
a first inverter that inverts the first internal signal and outputs an inverted first internal signal;
a second inverter that inverts the third internal signal and outputs an inverted third internal signal;
a first flip-flop that receives a first output signal and outputs the first bit, in response to the first internal signal;
a second flip-flop that receives the first bit and outputs the third bit and the first output signal having a logic value opposite to that of the third bit, in response to the inverted first internal signal;
a third flip-flop that receives a second output signal and outputs the fifth bit, in response to the third internal signal; and
a fourth flip-flop that receives the fifth bit and outputs the seventh bit and the second output signal having a logic value opposite to that of the seventh bit, in response to the inverted third internal signal.

21. The counter of claim 20, wherein the second and fourth flip-flops are reset in response to a clear signal.

22. The counter of claim 19, wherein the second output unit comprises:
a first inverter that inverts the second internal signal and outputs an inverted second internal signal;
a second inverter that inverts the fourth internal signal and outputs an inverted fourth internal signal;
a first flip-flop that receives a first output signal and outputs the second bit, in response to the second internal signal;
a second flip-flop that receives the second bit and outputs the fourth bit and the first output signal having a logic value opposite to that of the fourth bit, in response to the inverted second internal signal;
a third flip-flop that receives a second output signal and outputs the sixth bit, in response to the fourth internal signal; and
a fourth flip-flop that receives the sixth bit and outputs the eighth bit and the second output signal having a logic value opposite to that of the eight bit, in response to the inverted fourth internal signal.

23. The counter of claim 22, wherein the second and fourth flip-flops are respectively reset in response to a clear signal.

24. The counter of claim 16, further comprising a clock restoration circuit that restores the first to fourth internal signals, the first and second clock signals, and the input clock signal based on the first to eighth bits.

25. The counter of claim 24, wherein the clock restoration circuit comprises:
a first restoration circuit that restores the first to fourth internal signals based on the first to eighth bits; and
a second restoration circuit that restores the first and second clock signals and the input clock signal based on the first to fourth internal signals.

26. The counter of claim 25, wherein the first restoration circuit comprises:
a first XOR gate that outputs a restored first internal signal in response to the first bit and the third bit;
a second XOR gate that outputs a restored second internal signal in response to the second bit and the fourth bit;
a third XOR gate that outputs a restored third internal signal in response to the fifth bit and the seventh bit; and
a fourth XOR gate that outputs a restored fourth internal signal in response to the sixth bit and the eighth bit.

27. The counter of claim 25, wherein the second restoration circuit comprises:
a first XOR gate that outputs a restored first clock signal in response to the first internal signal and the third internal signal;
a second XOR gate that outputs a restored second clock signal in response to the second internal signal and the fourth internal signal; and
a third XOR gate that outputs a restored input clock signal in response to the restored first clock signal and the restored second clock signal.

28. The counter of claim 1, wherein the counting signal includes 2^{k} (K is a natural number greater than 1) bits, and the counting circuit comprises:
a first counting unit that executes a counting operation and outputs first to fourth internal signals, in response to the first and second clock signals;
a second counting unit that executes a counting operation and outputs the first to 2^{K} bits, in response to the first to fourth internal signals.

29. A two bit counter comprising:
a first inverter that inverts an input signal and outputs an inverted input signal; and
a counting circuit that executes a counting operation in response to the input signal and the inverted input signal and outputs a counting signal in response to the first and second clock signals, wherein each value from zero (0) to four (4) is outputted every 4 cycles of the input clock in a non-consecutive, non-monotonically increasing or decreasing fashion, the counting circuit comprising:
a first flip-flop that receives an output signal in response to the input signal and outputs the first bit; and
a second flip-flop that receives the first bit in response to the inverted input signal and outputs the second bit and the output signal having a logic value opposite to that of the second bit.

30. A four bit counter comprising:
a clock generator that generates first and second clock signals with different phases based on an input clock signal; and
a counting circuit that executes a counting operation and outputs a counting signal in response to the first and second clock signals, wherein each value from zero (0) to 2ⁿ minus one (1) is outputted every 2ⁿ cycles of the input clock in a non-consecutive, non-monotonically increasing or decreasing fashion, the counting circuit comprising:
a first inverter that inverts the first clock signal and outputs an inverted first clock signal;
a second inverter that inverts the second clock signal and outputs an inverted second clock signal;
a first flip-flop that receives a first output signal and outputs the first bit in response to the first clock signal;
a second flip-flop that receives the first bit, and outputs the third bit and the first output signal having a logic value opposite to that of the third bit, in response to the inverted first clock signal;
a third flip-flop that receives a second output signal and outputs the second bit in response to the second clock signal; and
a fourth flip-flop that receives the second bit, and outputs the fourth bit and the second output signal having a logic value opposite to that of the fourth bit, in response to the inverted second clock signal.
